(19) United States
(12) Patent Application Publication
(10) Pub. No.: US 2012/0206188 A1
(43) Pub. Date: Aug. 16, 2012

(54) SYSTEMS AND METHODS FOR DYNAMIC MOSFET BODY BIASING FOR LOW POWER, FAST RESPONSE VLSI APPLICATIONS

(75) Inventor: Tuan Anh Duong, Glendora, CA (US)

(73) Assignee: California Institute of Technology, Pasadena, CA (US)

(21) Appl. No.: 13/396,486

(22) Filed: Feb. 14, 2012

Related U.S. Application Data
(60) Provisional application No. 61/442,371, filed on Feb. 14, 2011.

(51) Int. Cl. H03K 17/687

(52) U.S. Cl. 327/437; 327/434

(57) ABSTRACT

Systems and methods in accordance with embodiments of the invention are disclosed that include MOSFET transistor operation by adjusting V_{bs}, or the voltage applied to the body terminal of the MOSFET transistor, to control the threshold voltage (Vₜₕ) in order to minimize leakage current and increase response time. One embodiment includes a n-channel metal-oxide-semiconductor field-effect transistor (NMOS), including: a gate terminal; a source terminal; a drain terminal; a body terminal; and control circuitry, where the control circuitry is configured to bias the body terminal at a first voltage when voltage applied to the gate terminal turns the transistor OFF and a second voltage when voltage applied to the gate terminal turns the transistor ON; and where the first voltage is of a lower value than the second voltage.

### CROSS-REFERENCE TO RELATED APPLICATIONS

The current application claims priority to U.S. Provisional Application No. 61/442,371, filed Feb. 14, 2011, the disclosure of which is incorporated herein by reference.

### STATEMENT OF FEDERALLY SPONSORED RESEARCH

The invention described herein was made in the performance of work under a NASA contract, and is subject to the provisions of Public Law 96-517 (35 USC 202) in which the Contractor has elected to retain title.

### FIELD OF THE INVENTION

The present invention generally relates to transistor operation and more specifically to the operation of metal-oxide-semiconductor field-effect transistors (MOSFET).

### BACKGROUND OF THE INVENTION

Electronic systems can be built of transistors to amplify or switch electronic signals. A transistor is typically composed of a semiconductor material with at least three terminals for connection to an external circuit. In a transistor, typically a voltage or current applied to one pair of the transistor's terminals changes the current flowing through another pair of terminals. A certain type of transistor, known as a field effect transistor (FET) utilizes either electrons (as an “N” type) or holes (as a “P” type) transistor for current flow, or for movement of electrically charged particles through a transmission medium. Current can flow due to the presence of electrons or the lack of electrons, which is termed an electron hole. A FET controls the flow of electrons or electron holes across a conductive channel between a source terminal and a drain terminal by affecting the size and shape of the conductive channel as influenced by voltage, or a lack of voltage, applied to a gate terminal on the FET. In that way, current also flows from the source terminal to a drain terminal. In certain cases, the body is another terminal that is connected to the substrate, or the material within which the conductive channel is formed. In common usage where a transistor has three terminals, the body terminal is directly connected with the source terminal, but does not need to be so. Generally, the conduction channel of a FET is doped to produce either an N-type or a P-type semiconductor where the drain and source terminals may be doped of an opposite type to the doping in the material of the conduction channel.

A metal-oxide-semiconductor field-effect transistor (MOSFET) is a commonly used FET where typically an insulator is used between the gate terminal and the body terminal. A representation of a typical NMOS is illustrated in FIG. 1A. The NMOS 100 includes gate 102, source 108, drain 104 and body 106 terminals. Similarly, a representation of a typical PMOS is illustrated in FIG. 1B. The PMOS 150 also includes gate 152, source 154, drain 158 and body 156 terminals. Transistors, such as an NMOS or PMOS and other circuit elements may be utilized as part of an integrated circuit, or a type of electronic circuit that includes a patterned diffusion of trace elements into the surface of a substrate of semiconductor material from where numerous circuit elements are connected.

There is an increased demand for smaller and more powerful electronic devices and thereby an increased demand for smaller and more powerful integrated circuits to create different types of integrated electronic devices. Very-large-scale integration (VLSI) is a technical field involving the creation of integrated circuits by combining a great number, billions in some instances, of transistors onto a single integrated circuit. The transistors in a VLSI system are typically miniaturized in order to fit an increasingly large number of transistors onto a single chip of a fixed size. Although miniaturization, such as decreasing transistor size to 50 nm and below, holds important design benefits in allowing for greater processing power in equal or smaller space, there are also design tradeoffs, such as increased power consumption due to both dynamic and leakage current, that serves as a constraint to inhibit the advantages of transistor feature size reduction. Additionally, when the feature sizes of transistors are reduced, the supply voltage (V_{dd}) and threshold voltage (Vₜₕ) are also reduced accordingly. This increases the sensitivity and noise susceptibility of a transistor as there is less room in the voltage swing from a transistor being active or ON with gate voltage above Vₜₕ and a transistor being non-active or OFF with gate voltage minimized below Vₜₕ. Additionally, the leakage current becomes a bigger factor of the total power consumption of transistors as well as transistors are miniaturized.

### SUMMARY OF THE INVENTION

Systems and methods in accordance with embodiments of the invention include MOSFET transistor operation by adjusting V_{bs}, or the voltage applied to the body terminal of the MOSFET transistor, to control the threshold voltage (Vₜₕ) in order to minimize leakage current and increase response time. One embodiment includes a n-channel metal-oxide-semiconductor field-effect transistor (NMOS), including: a gate terminal; a source terminal; a drain terminal; a body terminal; and control circuitry, where the control circuitry is configured to bias the body terminal at a first voltage when voltage applied to the gate terminal turns the transistor OFF and a second voltage when voltage applied to the gate terminal turns the transistor ON; and where the first voltage is of a lower value than the second voltage.

In a further embodiment, the first voltage is at or below zero volts.

In another embodiment, the second voltage is above zero volts.

In a still further embodiment, a first supply voltage is configured to supply power to the NMOS; and a second supply voltage is configured to supply power to the control circuitry, where the control circuitry is configured to dynamically bias the body terminal of the NMOS using the second supply voltage based upon the voltage applied to the gate terminal of the NMOS.

In still another embodiment, the control circuitry includes a pair of complementary transistors.

A yet further embodiment includes a p-channel metal-oxide-semiconductor field-effect transistor (PMOS), including: a gate terminal; a source terminal; a drain terminal; a body terminal; and control circuitry, where the control circuitry is configured to bias the body terminal at a first voltage when voltage applied to the gate terminal turns the transistor OFF and a second voltage when voltage applied to the gate terminal turns the transistor ON; and where the first voltage is of a higher value than the second voltage.

In yet another embodiment, the first voltage is at or above zero volts.

In a further embodiment again, the second voltage is below zero volts.

In another embodiment again, a first supply voltage configured to supply power to the PMOS; and a second supply voltage configured to supply power to the control circuitry, where the control circuitry is configured to dynamically bias the body terminal of the PMOS using the second supply voltage based upon the voltage applied to the gate terminal of the PMOS.

In a further additional embodiment, the control circuitry includes a pair of complementary transistors.

An another additional embodiment includes a method of operating a n-channel metal-oxide-semiconductor field-effect transistor (NMOS) with a gate terminal, source terminal, drain terminal and body terminal, where the method includes: applying a voltage to the gate of the NMOS that turns the transistor OFF and applying a first voltage to the body terminal of the NMOS using control circuitry; and applying a voltage to the gate of the NMOS that turns the transistor ON and applying a second voltage to the body terminal of the NMOS using the control circuitry; where the value of the first voltage is less than the value of the second voltage.

In a still yet further embodiment, the first voltage is at or below zero volts.

In still yet another embodiment, the second voltage is above zero volts.

A still further embodiment again includes supplying a first supply voltage to power the NMOS; and supplying a second supply voltage to the control circuitry, where the control circuitry is configured to dynamically bias the body terminal of the NMOS using the second supply voltage based upon the voltage applied to the gate terminal of the NMOS.

In a still another embodiment again, the control circuitry includes a pair of complementary transistors.

A still further additional embodiment includes a method of operating a p-channel metal-oxide-semiconductor field-effect transistor (PMOS) with a gate terminal, source terminal, drain terminal and body terminal, where the method includes: applying a voltage to the gate of the PMOS that turns the transistor OFF and applying a first voltage to the body terminal of the PMOS using control circuitry; and applying a voltage to the gate of the PMOS that turns the transistor ON and applying a second voltage to the body terminal of the PMOS using the control circuitry; where the value of the first voltage is greater than the value of the second voltage.

In still another additional embodiment, the first voltage is at or above zero volts.

In a yet further embodiment again, the second voltage is below zero volts.

A yet another embodiment again includes supplying a first supply voltage to power the PMOS; and supplying a second supply voltage to the control circuitry, where the control circuitry is configured to dynamically bias the body terminal of the PMOS using the second supply voltage based upon the voltage applied to the gate terminal of the PMOS.

In a yet further additional embodiment, the control circuitry includes a pair of complementary transistors.

### BRIEF DESCRIPTION OF THE DRAWINGS

FIG. 1A is a representation of an NMOS with gate, source, drain and body terminals.

FIG. 1B is a representation of a PMOS with gate, source drain and body terminals.

FIG. 2A illustrates a graph of Vₜₕ as a function of V_{bs} for both an NMOS and a PMOS transistor.

FIG. 2B illustrates an implementation of control circuitry used to dynamically bias the body terminal of an NMOS transistor for an optimal Vₜₕ based upon the gate voltage in accordance with an embodiment of the invention.

FIG. 2C illustrates an implementation of control circuitry used to dynamically bias the body terminal of a PMOS transistor for an optimal Vₜₕ based upon the gate voltage in accordance with an embodiment of the invention.

FIG. 3A is an inverter design capable of implementing dynamic body biasing to generate a more ideal threshold voltage (Vₜₕ) with a better response in accordance with an embodiment of the invention.

FIG. 3B illustrates simulation results of the inverter design of FIG. 3A for Vᵢₙ and Vₒᵤₜ plotted against voltage and time.

FIG. 4A is a static random-access memory (SRAM) design capable of implementing dynamic body biasing to generate a more ideal threshold voltage (Vₜₕ) with a better response in accordance with an embodiment of the invention.

FIG. 4B illustrates simulation results of the SRAM design of FIG. 4A for Vᵢₙ and V_{ctrl} plotted against voltage and time.

FIG. 4C illustrates simulation results of the SRAM design of FIG. 4A for Vₒᵤₜ plotted against voltage and time.

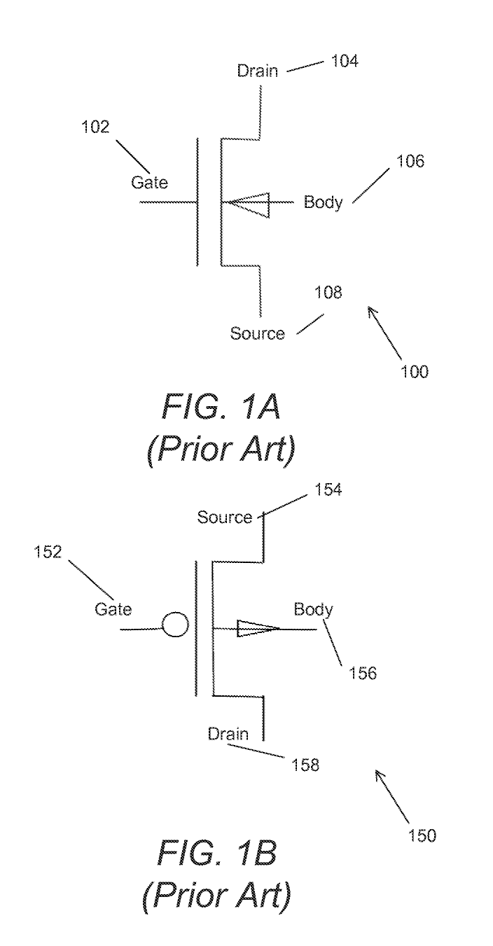

### DETAILED DESCRIPTION

Turning now to the drawings, systems and methods for MOSFET transistor operation involving adjusting V_{bs}, or the voltage applied to the body terminal of the MOSFET transistor, to control the threshold voltage (Vₜₕ) in order to minimize leakage current and increase response time in accordance with embodiments of the invention are illustrated. In many embodiments, V_{bs} is controlled to have a low absolute value so that Vₜₕ is high when a transistor is non-active, or OFF. Likewise in numerous embodiments, V_{bs} is controlled to have a high absolute value so that Vₜₕ is low when a transistor is active, or ON.

Furthermore, dynamically biasing a transistor's body dependent upon its intended operational state allows for a reduction of leakage current and wasted power during a transistor's off state by raising Vₜₕ. Additionally, dynamically biasing a transistor's body also allows for a faster and more effective response time for a transistor's ON state by reducing Vₜₕ when a transistor is ON and increasing Vₜₕ when a transistor is OFF, lowering the required voltage swing for transitioning logic states. This is beneficial from a power saving perspective by reducing the power consumed due to leakage current and during switching. A variety of circuits can be constructed that dynamically bias the body of transistors within a circuit to reduce power consumption and improve switching time, including by including multiple voltage sources that can be used to bias the body of specific transistors depending upon their intended operational state.

A threshold voltage (Vₜₕ) is a gate voltage value that allows sufficient electrical conductivity between the source and drain to make a low resistance, saturated, conducting path. The creation of a saturated low resistance current path allows for current to easily flow between the source and drain. A transistor ideally operates in a digital ON state where a transistor is active and the voltage applied to the gate allows for current to flow between the source and drain across a low resistance conductive channel at transistor saturation. This can be contrasted to an ideal digital OFF state where a transistor is not active and no voltage or a voltage below Vₜₕ is applied at the gate so that there is no current flow between the source and drain. However, transistors are typically non-ideal analog systems. In many instances, applying a voltage at the gate above Vₜₕ causes low resistance current flow between the source and drain. However, applying a voltage at the gate below Vₜₕ still causes a certain amount of current flow between the gate and source known as “leakage current” that muddies the digital OFF state of a transistor and generates unwanted power consumption.

Power consumption can be reduced in transistor operation below Vₜₕ, or subthreshold operation, by minimizing the voltage supply and/or by increasing Vₜₕ. Power consumption P of a MOSFET transistor is governed by the following equation where f is the frequency of the clock driving the transistor, I_{SC} is the short circuit current when an N and P channel are ‘ON’ simultaneously, C_{load} is load capacitor and I_{leakage} is the leakage current:

P=fC_{load}V_{dd}²+fI_{SC}V_{dd}+I_{leakage}V_{dd} (1)

As can be seen in the above equation 1, power consumption is influenced by the leakage current such that a reduction in the leakage current would also reduce the power consumption of the system. Leakage current is governed by the following equation where Vₜₕ is the threshold voltage, n is the sub threshold swing coefficient constant, γ is the linearized body effect coefficient, η is the Drain Induced Barrier Lowering (DIBL) coefficient, and I₀ is a constant associated upon the transistor itself:

$${I}_{leakage} = {I}_{0} exp ( \frac{{V}_{G} - {V}_{S} - {V}_{TO} - γ {V}_{S} + η {V}_{DS}}{{nV}_{th}} ) ( 1 - exp \frac{- {V}_{DS}}{{V}_{th}} ) \qquad ( 2 )$$

As can be seen in the above equation 2, a higher threshold voltage, Vₜₕ, will invariably lower leakage current, or I_{leakage}. Combined with equation 1, a lower leakage current would also lower power consumption as well.

The voltage applied to the body, V_{bs}, can control the threshold voltage, Vₜₕ. Threshold voltage (Vₜₕ) is governed by the following equation where Φ_{B} is the inversion layer potential, ε_{S} is the permittivity of the bulk material (which can be of silicon in some embodiments), Nₐ is the channel doping, Cₒₓ is the gate oxide capacitance, and q is the electron charge:

$$\begin{matrix}{V}_{th} = {V}_{to} + γ ( \sqrt{2 {Φ}_{B} - {V}_{BS}} - \sqrt{2 {Φ}_{B}} ) \\ With & ( 3 ) \\ γ = \frac{\sqrt{2 {ɛ}_{s} q {N}_{a}}}{{C}_{ox}} & ( 4 )\end{matrix}$$

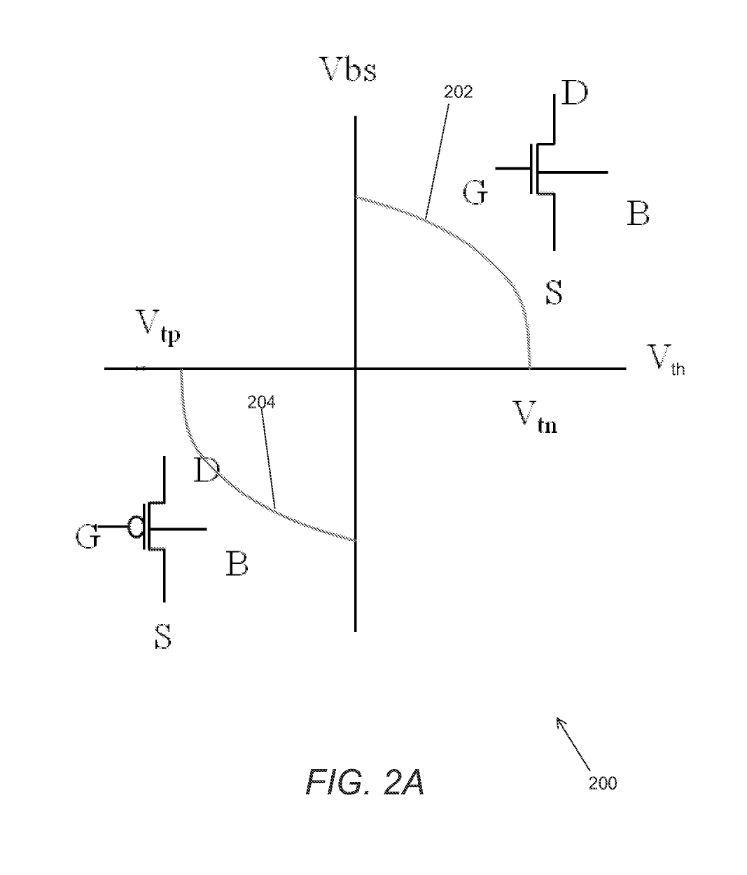

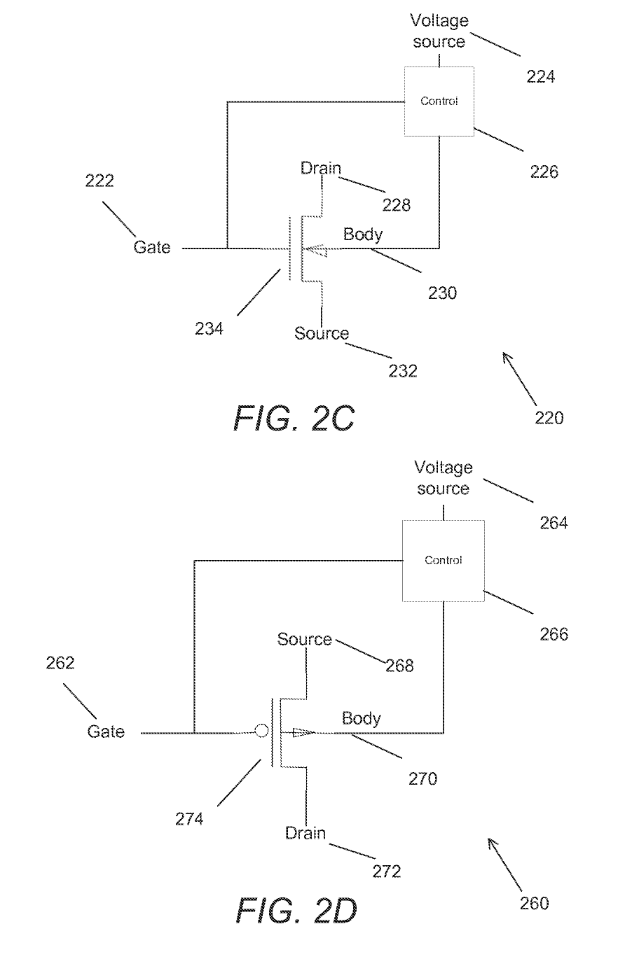

As can be seen in the above equation 3, changing V_{bs} will cause a corresponding change in Vₜₕ. A plot of V_{bs} relative to Vₜₕ with respect to both a PMOS and a NMOS transistor is illustrated in FIG. 2A. The plot 200 includes V_{bs} relative to Vₜₕ for an NMOS 202 as well as V_{bs} relative to Vₜₕ for a PMOS 204. As can be seen in FIG. 2A, a greater absolute value of V_{bs} yields a lower absolute value of Vₜₕ and a zero V_{bs} will likewise yield the greatest Vₜₕ value, notated in FIG. 2A as Vₜₕ for an NMOS and Vₜₚ for a PMOS. In many embodiments, when the transistor is active or on, Vₜₕ can be controlled by V_{bs} to be positive in an N type transistor or negative for P type transistor so that the current can be maximized to lower Vₜₕ, which enhances the amount of current I_{d} across the source and drain to improve transistor performance. Likewise, when a transistor not active or OFF, Vₜₕ is increased with a corresponding change in V_{bs}, which also reduces leakage current (as can be seen from equation 2) and also reduces power consumption (as can be seen from equation 1). Furthermore, either increasing or reducing Vₜₕ depending upon a transistor's intended operational state allows for a faster and more effective transistor response. In many embodiments, lowering Vₜₕ for an active transistor reduces the amount of voltage applied at the gate of the transistor to activate the transistor. Likewise, raising Vₜₕ for a non-active transistor also increases the voltage used to activate a transistor, increasing the transistor's robustness against noise and decreases leakage current and power consumption. This is especially useful for the miniaturized transistors used in VLSI applications as voltages, such as V_{dd} and Vₜₕ, are typically reduced as transistor size is reduced. Additionally, the reduction in voltages also reduces the voltage range at which a transistor can operate, decreasing the distinction between a transistor's ON and OFF state and increasing a transistor's susceptibility to noise. Dynamically lowering Vₜₕ to more easily turn a transistor ON and raising Vₜₕ to generate a more robust OFF state can thereby create more robust transistors.

Many different circuit designs can be implemented to dynamically control Vₜₕ of a MOSFET based upon the voltage applied at the gate for low power response in accordance with embodiments of the invention. In many embodiments, a control circuit can be utilized to control the voltage applied to the body based upon the voltage applied at the gate. A circuit including control circuitry to bias the body terminal of an NMOS for based upon voltage applied at the gate in accordance with an embodiment of the invention is illustrated in FIG. 2B. The circuit 220 includes an NMOS transistor 234 with gate 222, drain 228, source 232 and body 230 terminals. The circuit 230 also includes control circuitry 226 connected with a voltage source 224. The control circuitry controls the voltage applied to the body 230 of the NMOS transistor according to the operational state of the transistor (i.e. whether the voltage applied at the gate 222 of the transistor is configured to turn the transistor ON or OFF). In many embodiments, the bias voltage applied to the body terminal of the transistor is intended to control Vₜₕ to improve the performance of the transistor. As discussed above in FIG. 2A, V_{bs} can be adjusted to be of a larger positive value to reduce Vₜₕ with transistor ON operation. Likewise, V_{bs} can be adjusted to be a smaller positive value to increase the Vₜₕ with transistor OFF operation. Similarly, a circuit including control circuitry to bias the body terminal of a PMOS transistor based upon voltage applied at the gate in accordance with an embodiment of the invention is illustrated in FIG. 2C. The circuit 260 includes a PMOS transistor 274 with gate 262, drain 272, source 268 and body 270 terminals. The circuit 260 also includes control circuitry 266 connected with a voltage source 264 that applies a voltage to the body 270 of the PMOS transistor 274 according to the operational state of the transistor (i.e. whether the voltage applied at the gate 262 of the transistor is configured to turn the transistor ON or OFF). As discussed above in FIG. 2A, V_{bs} can be adjusted to be of a larger negative value to bring Vₜₕ closer to zero with transistor ON operation. Likewise, V_{bs} can be adjusted to be a smaller negative value to bring Vₜₕ farther from zero with transistor OFF operation. Essentially, a larger absolute value of V_{bs} yields a smaller absolute value of Vₜₕ for transistor ON operation and a smaller absolute value of V_{bs} yields a larger absolute value of Vₜₕ for transistor OFF operation. In both FIGS. 2B and 2C, any circuitry appropriate to controlling the bias voltage based upon the supply voltage of the control circuitry and the gate voltage can be utilized. In several embodiments, the supply voltage of the control circuitry differs from the supply voltage of the transistor, which is being dynamically biased by the control circuitry.

Although specific circuit designs and operational principles are discussed above, many different circuit designs are also capable of biasing a transistor's body to reduce leakage current and increase transistor response time in accordance with many different embodiments of the invention. Systems and methods for leakage current reduction and improved response time in accordance with embodiments of the invention are described in further detail below.

### Dynamic Body Biasing Circuit Implementations

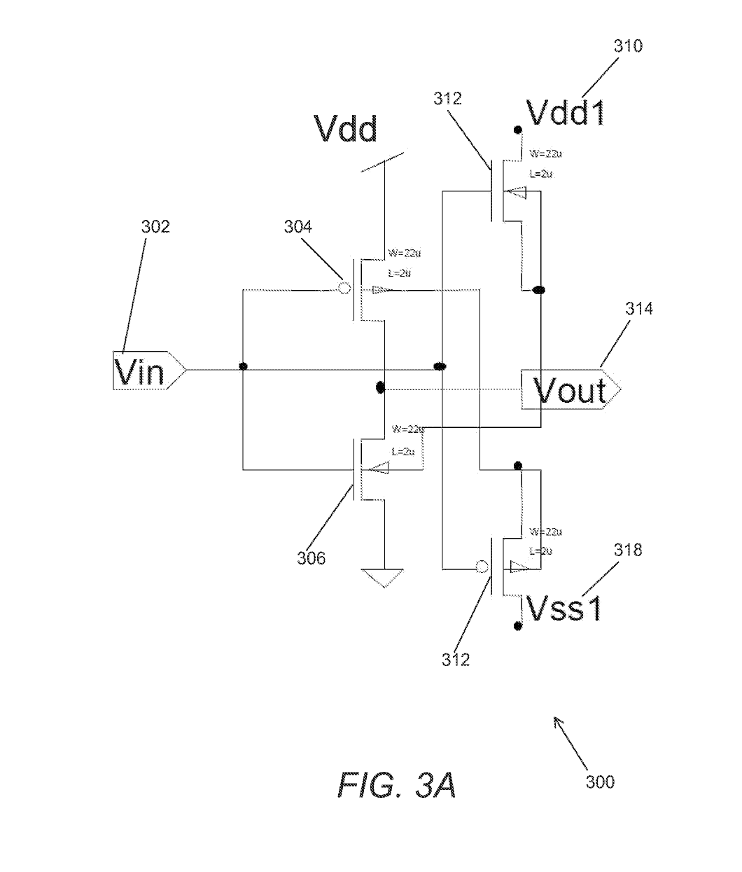

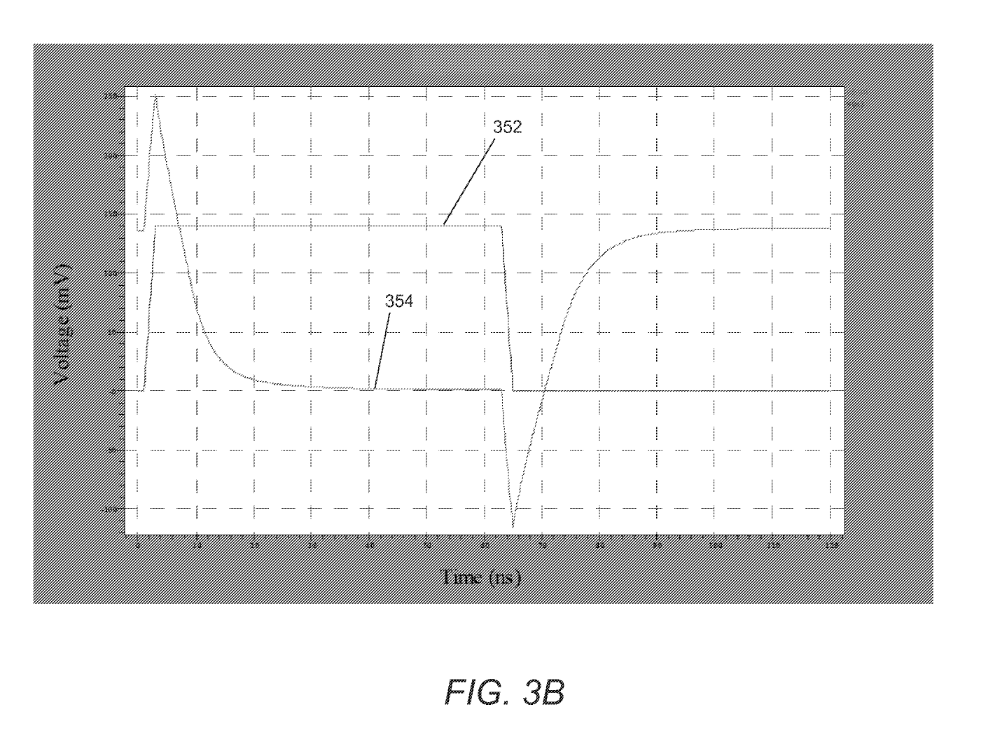

Many different circuit designs are capable of utilizing MOSFETs with Vₜₕ dynamically controlled with dynamic body biasing to generate a more ideal Vₜₕ and improved response time based upon the state of the MOSFET in accordance with many different embodiments of the invention. In several embodiments, circuitry that switches the bias voltage applied to the body terminal to control Vth is utilized. In certain embodiments, this can include using multiple supply voltages that can bias the body of a transistor dependent upon whether the transistor is operating in an intended ON or OFF state. A circuit layout implementing a complementary metal-oxide-semiconductor (CMOS) inverter with a control circuit for dynamic biasing to generate a more ideal Vₜₕ in accordance with an embodiment of the invention is illustrated in FIG. 3A. The circuit 300 includes an NMOS 306 and a PMOS 304 which act in conjunction as an inverter to invert a digital value at the input, Vᵢₙ 302, when measured at the output, Vₒᵤₜ 314. The circuit also includes additional voltage supplies, V_{ddl} 310 and Vₛₛₗ 318, which are used for biasing each body terminal of the transistors in the CMOS inverter to achieve a more ideal Vₜₕ and better response. The additional supply voltages, V_{ddl} 310 and Vₛₛₗ 318 are administered by control circuitry to bias the transistors of the CMOS inverter appropriate for each NMOS or PMOS. In the illustrated embodiment, the control circuitry is a complementary set of transistors 312 that utilize the additional supply voltages to bias each transistor's body as appropriate depending upon the voltage applied at the transistor's gate. The actual voltage passed can vary according to different applications. In many embodiments of the invention, a larger absolute value of V_{bs} yields a smaller absolute value of Vₜₕ for transistor ON operation and a smaller absolute value of V_{bs} yields a larger absolute value of Vₜₕ for transistor OFF operation as illustrated in FIG. 2A. In certain embodiments, a maximum absolute value of V_{bs} is applied for the minimum absolute value of Vₜₕ to achieve transistor ON operation and likewise a minimum absolute value of V_{bs} is applied for the maximum absolute value of Vₜₕ to achieve transistor OFF operation. In other embodiments, the absolute value of V_{bs} is increased during transistor ON operation and V_{bs} is decreased during transistor OFF operation.

The circuit of FIG. 3A was simulated in the Simulation Program with Integrated Circuit Emphasis (SPICE) using 0.13 um CMOS technology to compare circuit operation with a clock rate of 10 MHz under typical operation conditions where V_{dd} is set at 2.5V against a dynamic body biasing approach with power constraints where V_{dd} is set lower at 0.14V. Setting a lower voltage source, V_{dd} simulates power constrains in VLSI designs where the V_{dd} is typically lower given the large amount of transistors on a printed circuit board. The simulation results comparing leakage power, average power (rise/fall time), and power delay product between typical operating conditions and the power constrained dynamic body biasing approach is listed in the below table 1:

TABLE 1
Inverter comparison between typical operating conditions vs.
low power dynamic body biasing using 0.13 um CMOS technology

| | Leakage | Average Power | |
|---|---|---|---|
| | Power | (Watts)/rise and fall | Power-delay |
| | (Watts) | time | product |
| Typical operating | 1.8e−9 | 2.041e−6/1.4 ns | 2.8e−15 watts per |
| conditions | | | second |
| Power constrained | 7.8e−10 | 1.20e−10/15 ns | 1.5e−18 watts per |
| dynamic body biasing | | | second |

As can be seen in table 1 above, the dynamic body biasing technique even under lower power operation generates a favorable decrease in leakage power, average power/rise and fall time and the power delay product over typical operating conditions in the inverter circuit of FIG. 3A.

A plot of simulation results of the CMOS inverter circuit utilizing dynamic body biasing illustrated in FIG. 3A is illustrated in FIG. 3B. The simulation results plot both the input voltage, Vᵢₙ 352 and the output voltage Vₒᵤₜ 354 against time. As illustrated in FIG. 3B, when the square wave input, Vᵢₙ 352, is high, the response output, Vₒᵤₜ 354, is low and vice versa with a short switching time.

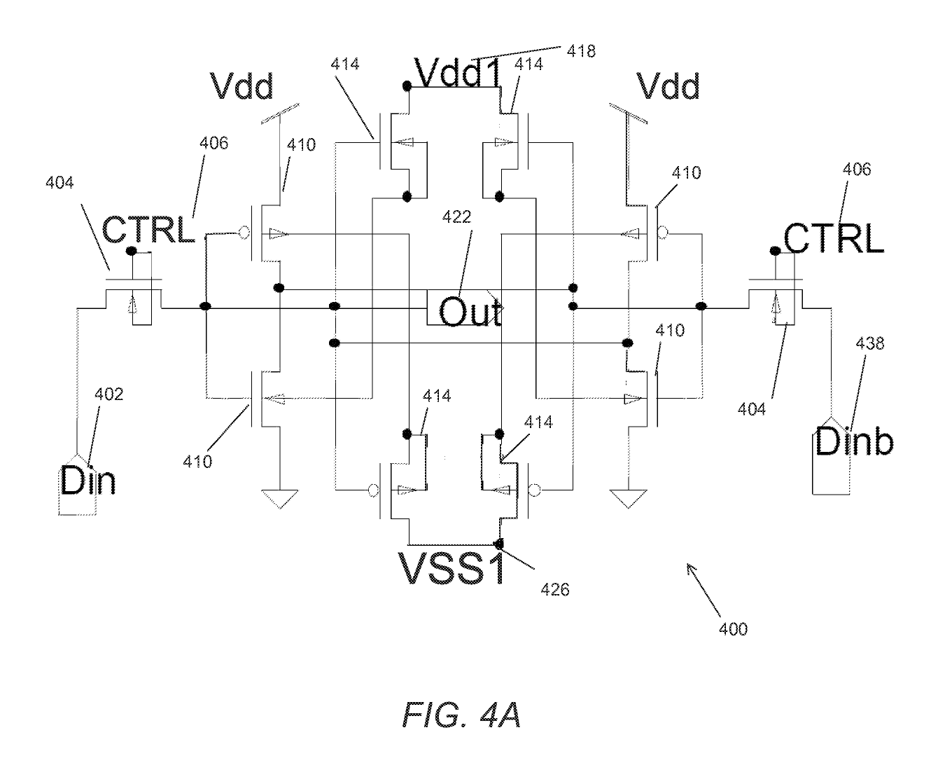

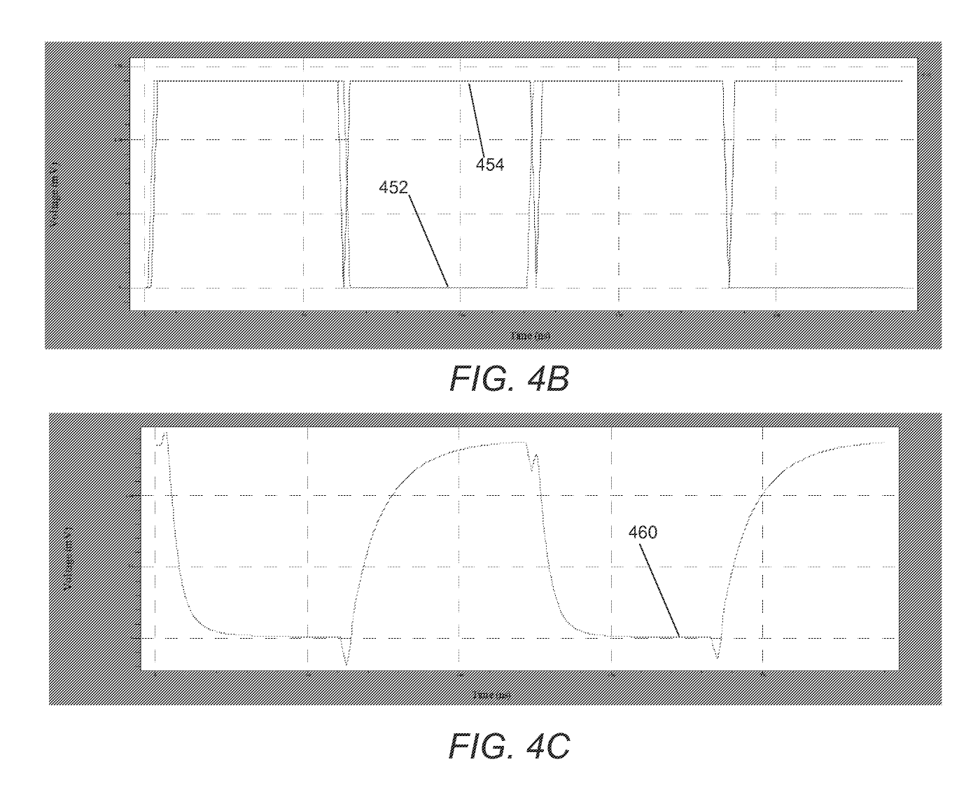

Although a CMOS inverter is discussed above, many different circuit architectures can implement dynamic body biasing by utilizing multiple voltage sources to bias a transistor's body terminal in order to generate a more ideal Vₜₕ and a better response in accordance with many different embodiments of the invention. For example, dynamic body biasing can be utilized in SRAM circuits. A SRAM circuit with a control circuit for dynamic biasing to generate a more ideal Vₜₕ in accordance with an embodiment of the invention is illustrated in FIG. 4A. The circuit 400 includes a set of two cross coupled CMOS inverters 410 that can store a logic value at the output 422 according to the logic value at the input Dᵢₙ 402 and inverse input D_{inb} 438. Two additional access transistors 404 with gate input CTRL 406 serve to control the access to the output 422, or storage cell 422, during read and write operation. In many embodiments, the body of a transistor may also be controlled for Vₜₕ by connecting the gate and body terminals, as illustrated by the access transistors 404 in the illustrated embodiment.

The circuit also includes additional voltage supplies, V_{ddl} 310 and Vₛₛₗ 318, which are used for biasing each body terminal of the transistors in the CMOS inverter to achieve a more ideal Vₜₕ and better response. The additional supply voltages, V_{ddl} 310 and Vₛₛₗ 318 are administered by control circuitry to bias the transistors of the CMOS inverter appropriate for each particular NMOS or PMOS. In the illustrated embodiment, the control circuitry is a complementary set of transistors 312 that pass an amount of voltage from the additional supply voltages to bias each transistor's body as appropriate depending upon the voltage applied at the transistor's gate. The actual voltage passed can vary according to different applications. In many embodiments of the invention, a larger absolute value of V_{bs} yields a smaller absolute value of Vₜₕ for transistor ON operation and a smaller absolute value of V_{bs} yields a larger absolute value of Vₜₕ for transistor OFF operation as illustrated in FIG. 2A. In certain embodiments, a maximum absolute value of V_{bs} is applied for the minimum absolute value of Vₜₕ to achieve transistor ON operation and likewise a minimum absolute value of V_{bs} is applied for the maximum absolute value of Vₜₕ to achieve transistor OFF operation. In other embodiments, the absolute value of V_{bs} is increased during transistor ON operation and V_{bs} is decreased during transistor OFF operation.

The circuit also includes additional voltage supplies, V_{ddl} 416 and Vₛₛₗ 426, which are used to bias each of the body terminals of the transistors in the cross coupled CMOS inverters 410 to achieve a more ideal Vₜₕ. The additional supply voltages, V_{ddl} 418 and Vₛₛₗ 426 are administered also by control circuitry that pass an amount of voltage from the additional supply voltages to bias the body of the transistors of the cross coupled CMOS inverters 410 in a manner similar to that outlined above with respect to the inverter illustrated in FIG. 3A. In the illustrated embodiment, the control circuitry is a complementary set of transistors 414.

The SRAM circuit shown in FIG. 4A was also simulated in SPICE to compare results using 0.13 um CMOS technology at a clock cycle of 10 MHz between typical operating conditions with V_{dd} at 2.5V and a dynamic body biasing approach with power constraints where V_{dd} is set lower at 0.14V. Simulation results for comparing leakage power, average power (rise and fall time) and power delay product between a conventional approach and this dynamic body biasing approach is listed in the below table 2:

TABLE 2
SDRAM comparison between an inverter under typical operating
conditions vs. low power dynamic body biasing using 0.13 um
CMOS technology

| | Leakage | Average Power | |
|---|---|---|---|
| | Power | (Watts)/rise and fall | |
| | (Watts) | time) | Power-delay product |
| Typical operating | 2.5e−9 | 3.017e−6/3n | 9.0e−15 watt · sec |
| conditions | | | |
| Power constrained | 1.75e−9 | 1.8e−9/20 ns | 3.6e−17 watt · sec |
| dynamic body | | | |
| biasing | | | |

Similar to the results for the inverter as can be seen in table 2 above, the dynamic body biasing technique even under lower power operation generates a favorable decrease in leakage power, average power/rise and fall time and the power delay product over typical operating conditions in the SRAM circuit of FIG. 4A.

A plot of simulation results of the SRAM circuit utilizing dynamic body biasing shown in FIG. 3A is illustrated in FIGS. 4B and 4C. The simulation results plot both the input voltage, Vᵢₙ 452 as well as the gate voltage of the access transistors, CTRL 454 against time in FIG. 4B as well as the output voltage Vₒᵤₜ 460 against time in FIG. 4C. As illustrated in FIG. 4B, when both the access transistor input CTRL 454 and the square wave input voltage, Vᵢₙ 452, is high, the response output voltage, Vₒᵤₜ 460, is low. Likewise, when both the access transistor input CTRL 454 and the square wave input voltage, Vᵢₙ 452 is low, the response output voltage, Vₒᵤₜ 460 is high. Although circuit designs are discussed above, any of a number of circuit designs can be utilized to implement dynamic body biasing by utilizing control circuitry to control Vₜₕ by biasing a transistor's body terminal based upon the voltage applied at the gate in order to generate a more ideal Vₜₕ in accordance with embodiments of the invention.

While the above description contains many specific embodiments of the invention, these should not be construed as limitations on the scope of the invention, but rather as an example of one embodiment thereof. It is therefore to be understood that the present invention may be practiced otherwise than specifically described, without departing from the scope and spirit of the present invention. Thus, embodiments of the present invention should be considered in all respects as illustrative and not restrictive.

What is claimed is:

1. An n-channel metal-oxide-semiconductor field-effect transistor (NMOS), comprising:
a gate terminal;
a source terminal;
a drain terminal;
a body terminal; and
control circuitry, wherein the control circuitry is configured to bias the body terminal at a first voltage when voltage applied to the gate terminal turns the transistor OFF and a second voltage when voltage applied to the gate terminal turns the transistor ON; and
wherein the first voltage is of a lower value than the second voltage.

2. The NMOS of claim 1, wherein the first voltage is at or below zero volts.

3. The NMOS of claim 1, wherein the second voltage is above zero volts.

4. The NMOS of claim 1, wherein:
a first supply voltage is configured to supply power to the NMOS; and
a second supply voltage is configured to supply power to the control circuitry, where the control circuitry is configured to dynamically bias the body terminal of the NMOS using the second supply voltage based upon the voltage applied to the gate terminal of the NMOS.

5. The NMOS of claim 1, wherein the control circuitry comprises a pair of complementary transistors.

6. A p-channel metal-oxide-semiconductor field-effect transistor (PMOS), comprising:
a gate terminal;
a source terminal;
a drain terminal;
a body terminal; and
control circuitry, wherein the control circuitry is configured to bias the body terminal at a first voltage when voltage applied to the gate terminal turns the transistor OFF and a second voltage when voltage applied to the gate terminal turns the transistor ON; and
wherein the first voltage is of a higher value than the second voltage.

7. The PMOS of claim 1, wherein the first voltage is at or above zero volts.

8. The PMOS of claim 1, wherein the second voltage is below zero volts.

9. The PMOS of claim 1, wherein:
a first supply voltage is configured to supply power to the PMOS; and
a second supply voltage is configured to supply power to the control circuitry, where the control circuitry is configured to dynamically bias the body terminal of the PMOS using the second supply voltage based upon the voltage applied to the gate terminal of the PMOS.

10. The PMOS of claim 1, wherein the control circuitry comprises a pair of complementary transistors.

11. A method of operating a n-channel metal-oxide-semiconductor field-effect transistor (NMOS) with a gate terminal, source terminal, drain terminal and body terminal, wherein the method comprises:
applying a voltage to the gate of the NMOS that turns the transistor OFF and applying a first voltage to the body terminal of the NMOS using control circuitry; and
applying a voltage to the gate of the NMOS that turns the transistor ON and applying a second voltage to the body terminal of the NMOS using the control circuitry;
wherein the value of the first voltage is less than the value of the second voltage.

12. The method of claim 11, wherein the first voltage is at or below zero volts.

13. The method of claim 11, wherein the second voltage is above zero volts.

14. The method of claim 11, further comprising:
supplying a first supply voltage to power the NMOS; and
supplying a second supply voltage to the control circuitry, where the control circuitry is configured to dynamically bias the body terminal of the NMOS using the second supply voltage based upon the voltage applied to the gate terminal of the NMOS.

15. The method of claim 11, wherein the control circuitry comprises a pair of complementary transistors.

16. A method of operating a p-channel metal-oxide-semiconductor field-effect transistor (PMOS) with a gate terminal, source terminal, drain terminal and body terminal, wherein the method comprises:
applying a voltage to the gate of the PMOS that turns the transistor OFF and applying a first voltage to the body terminal of the PMOS using control circuitry; and
applying a voltage to the gate of the PMOS that turns the transistor ON and applying a second voltage to the body terminal of the PMOS using the control circuitry;
wherein the value of the first voltage is greater than the value of the second voltage.

17. The method of claim 16, wherein the first voltage is at or above zero volts.

18. The method of claim 16, wherein the second voltage is below zero volts.

19. The method of claim 16, further comprising:
supplying a first supply voltage to power the PMOS; and
supplying a second supply voltage to the control circuitry, where the control circuitry is configured to dynamically bias the body terminal of the PMOS using the second supply voltage based upon the voltage applied to the gate terminal of the PMOS.

20. The method of claim 16, wherein the control circuitry comprises a pair of complementary transistors.
